(19) United States
(12) Patent Application Publication
(10) Pub. No.: US 2021/0384292 A1
(43) Pub. Date: Dec. 9, 2021

(54) INTEGRATION OF INDUCTORS WITH ADVANCED-NODE SYSTEM-ON-CHIP (SOC) USING GLASS WAFER WITH INDUCTORS AND WAFER-TO-WAFER JOINING

(71) Applicant: QUALCOMM Incorporated, San Diego, CA (US)

(72) Inventors: Karim ARABI, San Diego, CA (US); Ravindra Vaman SHENOY, Dublin, CA (US); Evgeni Petrovich GOUSEV, Saratoga, CA (US); Mete ERTURK, San Diego, CA (US)

(21) Appl. No.: 17/408,273

(22) Filed: Aug. 20, 2021

Related U.S. Application Data
(62) Division of application No. 14/843,964, filed on Sep. 2, 2015, now abandoned.

(51) Int. Cl. H01L 49/02; H01L 23/64; H01L 23/498

(52) U.S. Cl. CPC H01L 28/10; H01L 23/645; H01L 23/49833; H01L 2924/19011; H01L 2924/19103; H01L 2224/16265; H01L 23/49827; H01L 2224/16268; H01L 2924/19042; H01L 2224/16225; H01L 2924/15311; H01L 23/49822; H01L 23/49816; H01L 2224/16267

(57) ABSTRACT

A voltage regulator having a coil inductor is integrated or embedded in a system-on-chip (SOC) device. The coil inductor is fabricated on an inductor wafer with through vias, and the inductor wafer is joined with an SOC wafer for integration with the SOC device.

### RELATED APPLICATION

This application is a divisional of, and claims the benefit of, and incorporates by reference herein in its entirety, U.S. patent application Ser. No. 14/843,964 filed Sep. 2, 2015.

### FIELD OF DISCLOSURE

Various embodiments described herein relate to integrated circuit devices, and more particularly, to integrated circuit devices with voltage regulators.

### BACKGROUND

Voltage regulators have been implemented in conventional dedicated power management integrated circuits (PMICs). A conventional PMIC, which is separate from other integrated circuits on a circuit board, may have difficulty meeting the droop (transient) and power (efficiency) requirements of a modern multi-core application processor or communication processor, for example.

There has been a growing interest in integrating voltage regulators as part of system-on-chip (SOC) integrated circuit devices. Integrated voltage regulators, however, may present several challenges in chip design and layout. For example, passive components such as inductors and capacitors in voltage regulators may pose a design challenge, because passive components, such as inductors and capacitors, especially those with large inductance and capacitance values, typically have large form factors requiring large surface areas in a typical layout for a silicon SOC die.

Moreover, inductors in voltage regulators typically require very low resistances to minimize power losses in voltage regulation. In addition to occupying a significant amount of surface area of a typical silicon SOC die, such inductors may require thick metal traces on the SOC die in order to reduce the resistance values of the inductors. In advanced-node SOC wafer fabrication, however, such thick metal traces may not be feasible. Moreover, even if thick metal traces are implementable on a silicon SOC die, conventional fabrication processes for integrating inductors as part of a voltage regulator on a silicon SOC die may require several additional masks, thereby increasing the cost of fabrication.

### SUMMARY

Exemplary embodiments of the disclosure are directed to integrated circuit devices and methods of making the same. In an embodiment, a voltage regulator is integrated or embedded in a system-on-chip (SOC) device which also includes one or more circuits using the voltage supplied by the voltage regulator.

In an embodiment, a device is provided, the device comprising: a system-on-chip (SOC) wafer; an inductor wafer having first and second surfaces and a plurality of vias therethrough, the vias forming a plurality of sidewalls in the inductor wafer, wherein the first surface of the inductor wafer is disposed adjacent to the SOC wafer; a magnetic layer on at least a portion of the first surface of the inductor wafer; and a conductive layer disposed on the magnetic layer, on at least a portion of the second surface of the inductor wafer, and on at least some of the sidewalls formed by the vias in the inductor wafer.

In another embodiment, a device is provided, the device comprising: a voltage regulator, comprising: a die; an inductor wafer having first and second surfaces and a plurality of vias therethrough, the vias forming a plurality of sidewalls in the inductor wafer, wherein the first surface of the inductor wafer is disposed adjacent to the die; a magnetic layer on at least a portion of the first surface of the inductor wafer; and a plurality of conductors disposed within at least some of the vias in the inductor wafer, the conductors having respective first ends adjacent to the first surface of the inductor wafer and second ends adjacent to the second surface of the inductor wafer; and a system-on-chip (SOC) package configured to receive a power supply voltage from the voltage regulator, the SOC package having at least one conductor connected to at least one of the first and second ends of the conductors.

In another embodiment, a method of making a device is provided, the method comprising: providing a first wafer having a first surface and a second surface; forming a plurality of vias through the first and second surfaces of the first wafer, wherein the vias are defined by a plurality of sidewalls within the first wafer; forming a patterned magnetic layer on at least a portion of the first surface of the first wafer; forming a conductive layer on the patterned magnetic layer over the patterned magnetic layer, at least a portion of the second surface of the first wafer, and at least some of the sidewalls of the vias; and joining a second wafer to the first wafer.

In yet another embodiment, a method of making a device is provided, the method comprising: providing a system-on-chip (SOC) package; and forming a voltage regulator on the SOC package, comprising: providing an SOC die; providing an inductor wafer having first and second surfaces, wherein the first surface of the inductor wafer is disposed adjacent to the SOC die; forming a plurality of vias through the first and second surfaces of the inductor wafer, wherein the vias are defined by a plurality of sidewalls in the inductor wafer; and forming a plurality of conductors disposed within at least some of the vias in the inductor wafer, the conductors having respective first ends adjacent to the first surface of the inductor wafer and second ends adjacent to the second surface of the inductor wafer, wherein the SOC package is configured to receive a power supply voltage from the voltage regulator, the SOC package having at least one conductor connected to at least one of the first and second ends of the conductors.

### BRIEF DESCRIPTION OF THE DRAWINGS

The accompanying drawings are presented to aid in the description of embodiments of the disclosure and are provided solely for illustration of the embodiments and not limitation thereof

FIG. 1 is a perspective view illustrating an embodiment of a system-on-chip (SOC) wafer.

FIG. 2 is a perspective view illustrating an embodiment of an inductor wafer with through vias.

FIG. 3 is a perspective view illustrating an embodiment of face-to-face wafer-to-wafer bonding of an SOC wafer and an inductor wafer.

FIG. 4 is a sectional view illustrating an embodiment of a first process step in the manufacturing of an inductor on an inductor wafer with through vias.

FIG. 5 is a sectional view illustrating an embodiment of a second process step in the manufacturing of the inductor with a patterned thin-film magnetic layer.

FIG. 6 is a sectional view of an embodiment of a third process step in the manufacturing of the inductor with a dielectric on the thin-film magnetic layer.

FIG. 7 is a sectional view of an embodiment of a fourth process step in the manufacturing of the inductor with metal plating.

FIG. 8 is a top plan view of an inductor having a coil with multiple loops.

FIG. 9 is a sectional view illustrating an embodiment of a fifth process step in the manufacturing of a system-on-chip (SOC) device by joining an SOC wafer with an inductor wafer.

FIG. 10 is a sectional view illustrating an embodiment of the SOC device of

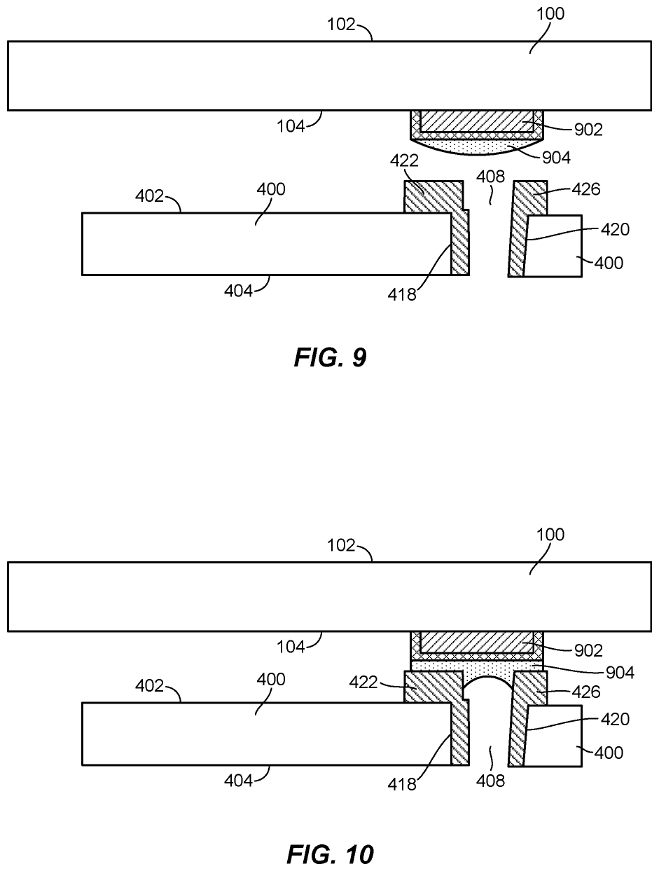

FIG. 9 after the SOC wafer and the inductor wafer are joined together.

FIG. 11 is a perspective view illustrating an embodiment of an inductor die after dicing of the joined SOC wafer and inductor wafer.

FIG. 12 is a sectional view illustrating an embodiment of a system including a printed circuit board (PCB), an SOC package, and a voltage regulator which includes an inductor die.

FIG. 13 is a diagram illustrating am embodiment of a system including a power management integrated circuit (PMIC) and an SOC device which includes an integrated or embedded voltage regulator and circuit using the voltage regulator.

### DETAILED DESCRIPTION

Aspects of the disclosure are described in the following description and related drawings directed to specific embodiments. Alternate embodiments may be devised without departing from the scope of the disclosure. Additionally, well-known elements will not be described in detail or will be omitted so as not to obscure the relevant details of the disclosure.

The word “exemplary” is used herein to mean “serving as an example, instance, or illustration.” Any embodiment described herein as “exemplary” is not necessarily to be construed as preferred or advantageous over other embodiments. Likewise, the term “embodiments” does not require that all embodiments include the discussed feature, advantage or mode of operation.

The terminology used herein is for the purpose of describing particular embodiments only and is not intended to be limiting of the embodiments. As used herein, the singular forms “a,” “an” and “the” are intended to include the plural forms as well, unless the context clearly indicates otherwise. It will be further understood that the terms “comprises,” “comprising,” “includes” or “including,” when used herein, specify the presence of stated features, integers, steps, operations, elements, and/or components, but do not preclude the presence or addition of one or more other features, integers, steps, operations, elements, components, or groups thereof. Moreover, it is understood that the word “or” has the same meaning as the Boolean operator “OR,” that is, it encompasses the possibilities of “either” and “both” and is not limited to “exclusive or” (“XOR”), unless expressly stated otherwise. It is also understood that the symbol “/” between two adjacent words has the same meaning as “or” unless expressly stated otherwise. Moreover, phrases such as “connected to,” “coupled to” or “in communication with” are not limited to direct connections unless expressly stated otherwise.

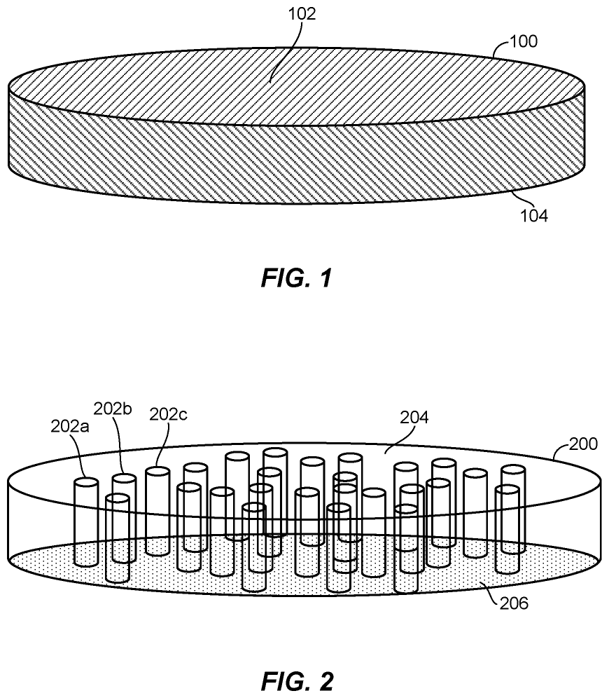

FIG. 1 is a perspective view illustrating an embodiment of a system-on-chip (SOC) wafer 100 having a first surface 102 and a second surface 104 opposite each other. In an embodiment, the SOC wafer 100 comprises a semiconductor wafer, such as a silicon wafer. In alternate embodiments, the SOC wafer 100 may comprise a glass wafer, a quartz wafer, an organic wafer, or a wafer made of another material. In an embodiment, the SOC wafer 100 may be integrated with an inductor wafer on which one or more inductors are provided.

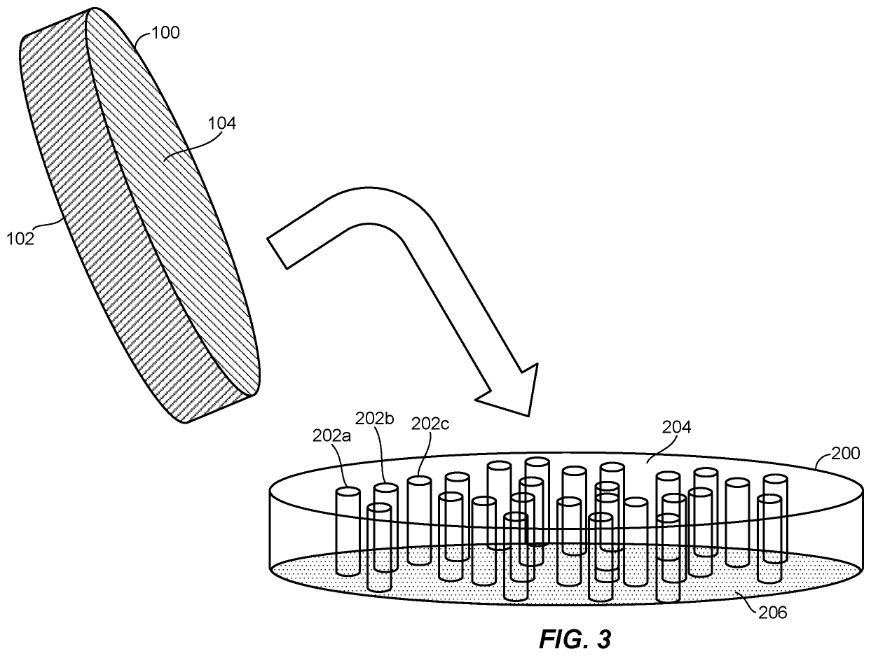

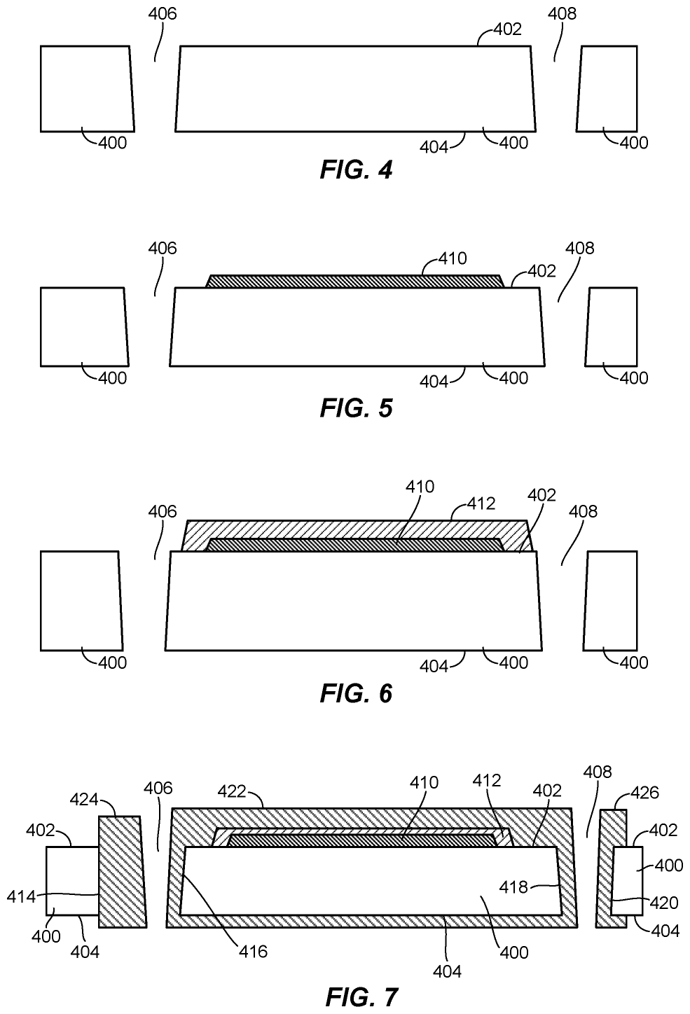

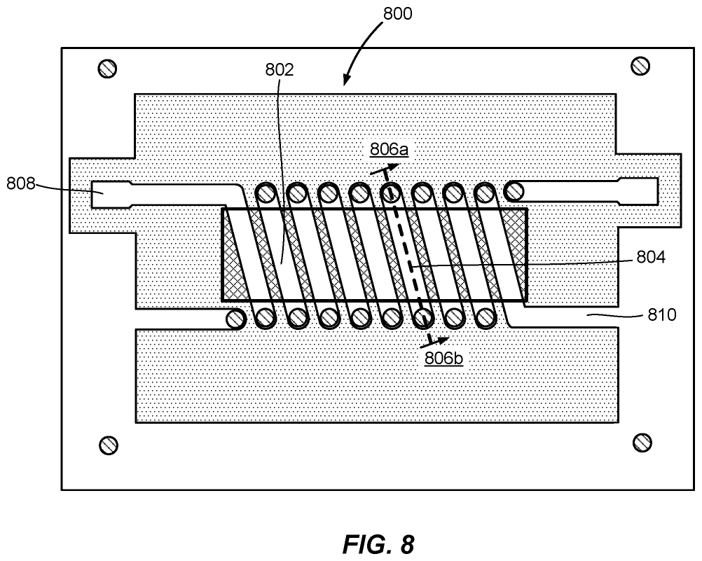

FIG. 2 is a perspective view illustrating an embodiment of an inductor wafer 200 with a plurality of through vias 202a, 202b, 202c, . . . . In the embodiment illustrated in FIG. 2, the inductor wafer 200 has first and second surfaces 204 and 206 opposite each other, and the vias 202a, 202b, 202c, . . . are formed through the first and second surfaces 204 and 206 of the inductor wafer 200. In an embodiment, the inductor wafer 200 comprises a glass wafer. In alternate embodiments, the inductor wafer 200 may comprise a quartz wafer, an organic wafer, or another type of low-loss dielectric material, to ensure that the inductor fabricated on the inductor wafer 200 has a low parasitic loss. For simplicity of illustration, detailed structure of the conductors in the vias 202a, 202b, 202c, . . . and the patterned conductive layers on the first and second surfaces 204 and 206 of the inductor wafer 200 which form one or more coils of an integrated inductor are not shown in the perspective view of FIG. 2. Embodiments of the integrated inductor formed on the inductor wafer 200 will be described in further detail below with respect to FIGS. 4-7 and the top plan view of FIG. 8.

FIG. 3 is a perspective view illustrating an embodiment of face-to-face wafer-to-wafer bonding of the SOC wafer 100 and the inductor wafer 200. In this embodiment, the second surface 104 of the SOC wafer 100 is joined with the first surface 204 of the inductor wafer 200. Again, detailed structure of the integrated inductor formed on the inductor wafer 200 is omitted in FIG. 3 for simplicity of illustration. Embodiments of the integrated inductor formed on the inductor wafer 200 will be described with respect to FIGS. 4-8.

FIG. 4 is a sectional view illustrating an embodiment of a first process step in the manufacturing of an inductor on an inductor wafer with through vias. In FIG. 4, an inductor wafer 400 having a first surface 402 and a second surface 404 is provided. The inductor wafer 400 may be a glass wafer, a quartz wafer, or another type of wafer made of a low-loss dielectric material, for example. In the embodiment shown in FIG. 4, first and second vias 406 and 408 are formed within the inductor wafer 400 through the first and second surfaces 402 and 404.

FIG. 5 is a sectional view illustrating an embodiment of a second process step in the manufacturing of the inductor with a magnetic layer. In FIG. 5, a magnetic layer, such as a patterned thin-film magnetic layer 410, is formed on the first surface 402 of the inductor wafer 400. In the embodiment illustrated in FIG. 5, the patterned thin-film magnetic layer 410 is formed on the first surface 402 of the portion of the inductor wafer 400 between the first and second vias 406 and 408.

The patterned thin-film magnetic layer 410 may be fabricated in various manners. For example, a magnetic material, such as cobalt-tantalum-zirconium (CoTaZr), may be deposited by vacuum processes, plated, screen-printed, or laminated onto the first surface 402 of the inductor wafer 400 to form the thin-film magnetic layer 410. Other magnetic materials, such as alloys of nickel-iron (NiFe), cobalt-iron (CoFe), or cobalt-nickel-iron (CoNiFe), with added materials such as phosphorus (P), boron (B) or carbon (C), may be used for the patterned thin-film magnetic layer 410 to tailor the magnetic and electrical properties of the patterned thin-film magnetic layer 410. In an embodiment, the magnetic material for the patterned thin-film magnetic layer 410 is chosen so as to enable a boost in the inductance value of the inductor at the appropriate operating frequencies. Other types of magnetic materials may also be implemented as the patterned thin-film magnetic layer 410. The magnetic layer 410 may also be formed by other techniques, for example, by sputtering a magnetic material on the first surface 402 of the inductor wafer 400.

FIG. 6 is a sectional view of an embodiment of a third process step in the manufacturing of the inductor with a dielectric on the patterned thin-film magnetic layer. In FIG. 6, a dielectric layer 412 is formed on top of the patterned thin-film magnetic layer 410. In the embodiment illustrated in FIG. 6, the dielectric layer 412 covers the entire top and side surfaces of the thin-film magnetic layer 410, as well as portions of the first surface 402 of the inductor wafer 400 surrounding the patterned thin-film magnetic layer 410. In an embodiment, the dielectric layer 412 comprises a polymer dielectric material. In an alternate embodiment, the dielectric layer 412 comprises an inorganic dielectric material, for example, silicon dioxide (SiO₂). Other types of dielectric materials may also be used for the dielectric layer 412 within the scope of the disclosure.

FIG. 7 is a sectional view of an embodiment of a fourth process step in the manufacturing of the inductor with metal plating. In the sectional view shown in FIG. 7, the first via 406 has sidewalls 414 and 416, and likewise, the second via 408 has sidewalls 418 and 420 between the first and second surfaces 402 and 404 of the inductor wafer 400. In an embodiment, a conductive layer 422 is formed on the dielectric layer 412, on the sidewall 416 of the first via 406, on the sidewall 418 of the second via 408, and on the second surface 404 of the inductor wafer 400 between the first and second vias 406 and 408. In an embodiment, the conductive layer 422 is formed by metal plating.

In a further embodiment, the conductive layer is formed by semi-additive plating of a metal such as copper (Cu). In the sectional view shown in FIG. 7, the sidewall 414 opposite the sidewall 416 the first via 406 and at least portions of the first and second surfaces 402 and 404 of the inductor wafer 400 adjacent to the sidewall 414 are also covered by a conductive layer 424. Likewise, as shown in FIG. 7, the sidewall 420 opposite the sidewall 418 the second via 408 and at least portions of the first and second surfaces 402 and 404 of the inductor wafer 400 adjacent to the sidewall 420 are also covered by a conductive layer 426. Similar to the conductive layer 422, the conductive layers 424 and 426 may also be formed by metal plating, such as semi-additive copper plating.

In the embodiment illustrated in the sectional view of FIG. 7, the conductive layer 422 is shown as a section of one loop of an inductor coil which comprises a plurality of loops. A top plan view of an embodiment of a solenoid inductor which comprises an inductor coil with multiple loops is shown in FIG. 8, which will be described in further detail below. Other inductor topologies, for example, spiral inductors, toroid inductors, or racetrack inductors, may also be implemented instead of the solenoid inductor in the embodiments described and illustrated herein. In an SOC package with a limited amount of space, however, a solenoid inductor may be chosen for its small footprint and easy, efficient integration closest to the circuitry on the SOC die.

Referring to the embodiment shown in FIG. 7, the conductive layer 422, which is illustrated as the sectional view of one loop of coil of an inductor, surrounds the thin-film magnetic layer 410, which is implemented as a magnetic core of the inductor. In an alternate embodiment, another magnetic layer may be provided within the inductor coil, for example, a magnetic layer formed on the second surface 404 of the inductor wafer 400 opposite the magnetic layer 410 as shown in FIG. 7, to increase the overall magnetic flux and thus the overall inductance of the inductor. In another alternate embodiment, an inductor with multiple loops of coil, with each loop having a sectional view similar to the sectional view of the conductive layer 422 as shown in FIG. 7, may be provided without any magnetic layer inside the coil, although such an inductor with no magnetic core would have a lower inductance compared to an inductor of the same size and the same number of loops having one or more magnetic cores.

FIG. 8 is a top plan view of an inductor 800 having a coil 802 with multiple loops before the SOC wafer is joined with the inductor wafer. In an embodiment, a sectional view of one of the loops 804 taken along sectional line 806a-806b is illustrated in FIG. 7. Referring to the top plan view of FIG. 8, the inductor 800 has two terminals 808 and 810 at two opposite ends of the coil 802 for electrical connections with other circuit components in a voltage regulator, for example. In an embodiment, some of the pass-through vias in the inductor wafer 400, like the first via 406 and the second via 408 as illustrated in FIGS. 4-7, may be used to form electrical connections between die pads on the SOC die and pads on the substrate. For example, some of the pass-through vias may be connected to enable power supply connections and/or to provide ground planes to improve power delivery to the SOC die. In an embodiment, the conductive layer 422, which may comprise a thick Cu plating on the inductor wafer 200, can be used as an additional routing layer to improve the performance of an advanced node SOC device with an advanced node SOC wafer 100. In a further embodiment, by using a combined design of the advanced node SOC wafer 100, the inductor wafer 200, and a package substrate 1212 on an integrated circuit (IC) package 1204, which will be described in further detail below with respect to FIG. 12, the thick Cu plating of the conductive layer 422 can be used to reduce the number of Cu layers in the advanced node SOC wafer 100, or in the package substrate 1212, or both.

FIG. 9 is a sectional view illustrating an embodiment of a fifth process step in the manufacturing of a system-on-chip (SOC) device by joining an SOC wafer with an inductor wafer. In an embodiment, the SOC wafer 100 is provided with a plurality of metal columns, such as metal column 902 on the second surface 104 of the SOC wafer. In an embodiment, a solder 904 is provided on the metal column 902 for joining with a respective metal-plated via of the inductor wafer. In the sectional view illustrated in FIG. 9, the metal column 902 on the second surface 104 of the SOC wafer 100 is aligned with the via 408 in the inductor wafer 400, which is described above with respect to FIG. 7. For simplicity of illustration, the thin-film magnetic layer 410 and the dielectric layer 412 are omitted in the sectional view of FIG. 9.

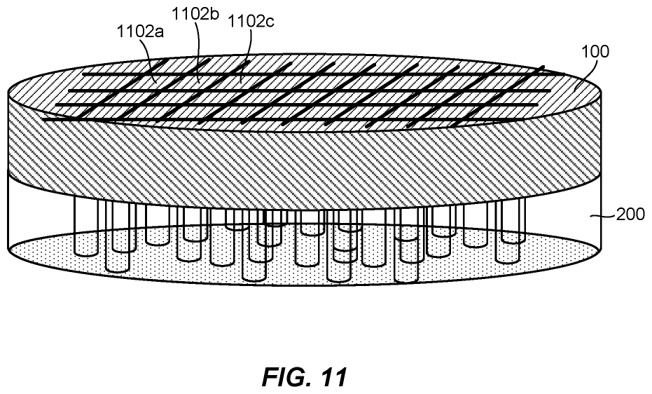

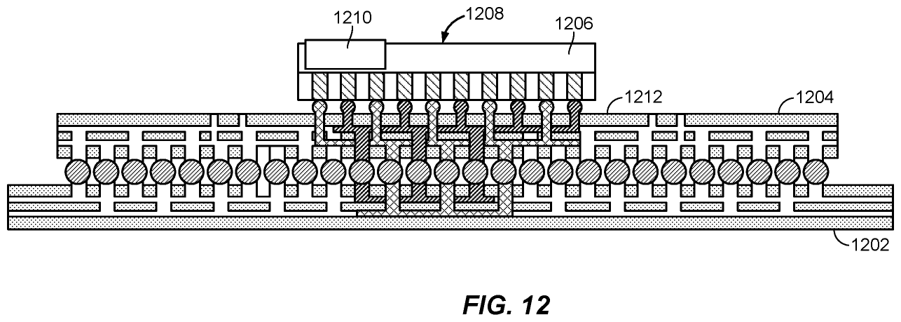

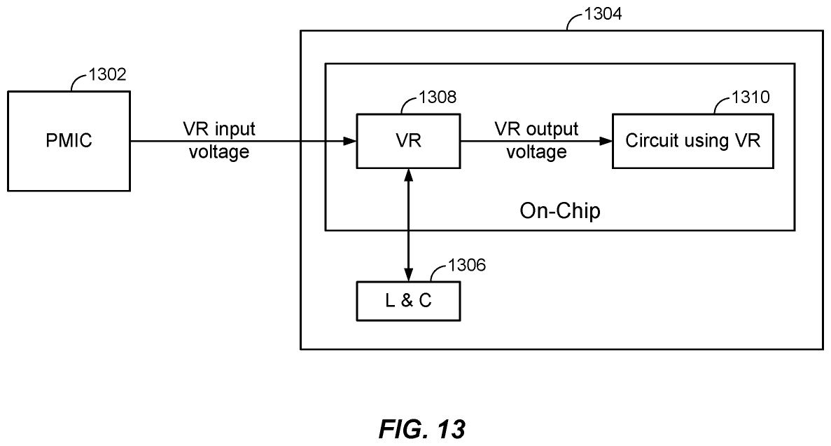

FIG. 10 is a sectional view illustrating an embodiment of the SOC device of FIG. 9 after the SOC wafer and the inductor wafer are joined together. In the embodiment illustrated in FIG. 10, the solder 904 connects the top portions of conductors 422 and 426 over the sidewalls 418 and 420 of the via 408, respectively, and is positioned directly over the via 408 in the inductor wafer 400. In an embodiment, the solder 904 may comprise a conventional solder material that melts under heat and solidifies when the temperature cools down.

FIG. 11 is a perspective view illustrating an embodiment of an inductor die after dicing of the joined SOC wafer and inductor wafer. In typical wafer fabrication processes, multiple identical chips may be fabricated on a single wafer with a large surface area. In an embodiment, a chip may be separated from a wafer by one of many dicing techniques known to persons skilled in the art. In the embodiment shown in FIG. 11, the joined SOC wafer 100 and the inductor wafer 200 may be diced into a plurality of dies 1102a, 1102b, 1102c, . . . . Any one of the dies 1102a, 1102b, 1102c, . . . may include one or more inductors and one or more other components, such as one or more capacitors, as part of an integrated or embedded voltage regulator.

FIG. 12 is a sectional view illustrating an embodiment of a system including a printed circuit board (PCB), an SOC package, and a voltage regulator which includes an inductor die. In FIG. 12, a printed circuit board (PCB) 1202 is provided, and an IC package 1204 is provided on the PCB 1202. In an embodiment, the IC package may include one or more analog integrated circuits, one or more digital integrated circuits, or a combination thereof. In an embodiment, the IC package 1204 may have one of various configurations known to persons skilled in the art, including but not limited to wirebond, flip-chip, or ball grid array (BGA), for example.

Referring to FIG. 12, a die 1206 that includes an inductor fabricated on an inductor wafer with through vias and joined with an SOC wafer in embodiments described above with respect to FIGS. 1-11 is integrated with the IC package 1204. In an embodiment, the IC package 1204 includes a package substrate 1212. In an embodiment, the die 1206 may be provided as a part of the circuitry for an integrated or embedded voltage regulator 1208, which may also include other components. For example, the voltage regulator 1208 may include one or more additional passive components such as one or more capacitors. In FIG. 12, the rest of the circuitry for the voltage regulator 1208 are generically indicated by block 1210.

FIG. 13 is a simplified block diagram illustrating am embodiment of a system including a power management integrated circuit (PMIC) and an SOC device which includes an integrated or embedded voltage regulator and circuit using the voltage regulator. In the embodiment illustrated in FIG. 13, the PMIC 1302 is shown as a chip separate from the SOC device 1304. In an alternate embodiment, the PMIC 1302 may be integrated as part of the SOC device 1304. Referring to FIG. 13, the SOC device includes an inductor and capacitor (L & C) block 1306, a voltage regulator (VR) 1308, and one or more circuits 1310 using the output voltage from the VR 1308. In an embodiment, the inductor and capacitor in the L & C block 1306 may be integrated or embedded with the VR 1308 on the same chip as the circuits 1310 using the output voltage from the VR 1308 in an SOC device.

While the foregoing disclosure shows illustrative embodiments, it should be noted that various changes and modifications could be made herein without departing from the scope of the appended claims. The functions, steps or actions of the method claims in accordance with embodiments described herein need not be performed in any particular order unless expressly stated otherwise. Furthermore, although elements may be described or claimed in the singular, the plural is contemplated unless limitation to the singular is explicitly stated.

What is claimed is:

1. A device, comprising:
a voltage regulator, comprising:
a die;
an inductor wafer having first and second surfaces and a plurality of vias therethrough, the vias forming a plurality of sidewalls in the inductor wafer, the first surface of the inductor wafer disposed adjacent to the die;
a magnetic layer on at least a portion of the first surface of the inductor wafer; and
a plurality of conductors disposed within at least some of the vias in the inductor wafer, the conductors having respective first ends adjacent to the first surface of the inductor wafer and second ends adjacent to the second surface of the inductor wafer; and
a system-on-chip (SOC) package configured to receive a power supply voltage from the voltage regulator, the SOC package having at least one conductor connected to at least one of the first and second ends of the conductors.

2. The device of claim 1, further comprising a printed circuit board (PCB) coupled to the SOC package.

3. The device of claim 1, wherein the magnetic layer comprises a thin-film magnetic layer.

4. The device of claim 1, wherein the voltage regulator further comprises a plurality of additional conductors disposed on the first and second surfaces of the inductor wafer, the additional conductors on the first and second surfaces of the inductor wafer and the conductors within at least some of the vias in the inductor wafer forming a coil of an inductor.

5. The device of claim 4, wherein the coil at least partially surrounds the magnetic layer.

6. The device of claim 1, wherein the inductor wafer comprises a glass wafer.

7. The device of claim 1, wherein the inductor wafer comprises a quartz wafer.
